(19) United States
(12) Patent Application Publication
(10) Pub. No.: US 2026/0353735 A1
(43) Pub. Date: Nov. 5, 2026

(54) CHALCOGENIDE-BASED THIN FILM MODIFIER, AND SEMICONDUCTOR SUBSTRATE AND SEMICONDUCTOR DEVICE FABRICATED USING THE SAME

(71) Applicant: SOULBRAIN CO., LTD., Gyeonggi-do (KR)

(72) Inventors: Jae Sun JUNG, Gyeonggi-do (KR); Seung Hyun LEE, Gyeonggi-do (KR); Deok Hyun KIM, Gyeonggi-do (KR)

(21) Appl. No.: 19/113,332

(22) PCT Filed: Oct. 6, 2023
(86) PCT No.: PCT/KR2023/015458

§ 371 Date: Mar. 19, 2025

(30) Foreign Application Priority Data
Oct. 7, 2022 (KR) 10-2022-0128694
Jan. 10, 2023 (KR) 10-2023-0003402
Jan. 13, 2023 (KR) 10-2023-0005228
Oct. 6, 2023 (KR) 10-2023-0133351

(51) Int. Cl. H10D 62/82

(52) U.S. Cl. CPC H10D 62/82

(57) ABSTRACT

The present invention relates to a chalcogenide-based thin film modifier, and a semiconductor substrate and semiconductor device fabricated using the same. According to a method of manufacturing a metalloid-containing thin film of the present invention, by using a precursor compound containing a halogen and a specific chalcogenide-based thin film modifier that may fill the site of the halogen that is released from the precursor compound, a thin film having high purity and improved reliability may be easily manufactured using a simple process.

### TECHNICAL FIELD

The present invention relates to a chalcogenide-based thin film modifier, and a semiconductor substrate and semiconductor device fabricated using the same. More particularly, the present invention relates to a chalcogenide-based thin film modifier forming a Ge—Sb—Te (GST) triple layer and being capable of significantly improving the deposition rate of a thin film by using a thin film modifier and significantly reducing impurities to improve the reliability of phase change devices, and a semiconductor substrate and semiconductor device fabricated using the same.

### BACKGROUND ART

Chalcogenides, which are referred to as compounds containing group 16 chalcogen elements, can have a characteristic of rapidly changing phase between a crystalline state and an amorphous state when heat is applied, and a phase change memory device can be implemented by using this characteristic.

In forming data storage materials applied to phase change memory devices, precursor materials, process conditions such as deposition temperature, and the content of carbon compounds as by-products in a chalcogenide-based thin film can have a significant impact on the quality and performance of the data storage material.

Generally, materials such as GeTe2 may be formed using a germanium precursor with an oxidation state of 4. However, the precursor has poor phase change characteristics, making it difficult to secure the reliability of phase change devices, and a problem occurs in which Te is precipitated during the phase change operation.

In addition, since deposition usually occurs at low temperatures of less than 200° C. a technology of completely removing the ligand of a precursor is required.

Accordingly, there is a need to develop a chalcogenide-based thin film modifier with excellent reactivity that can secure the reliability of phase change devices, improve the problem of Te precipitation during the phase change operation, and completely remove the ligand in a precursor, and a semiconductor substrate and semiconductor device fabricated using the chalcogenide-based thin film modifier.

In addition, in addition to the aforementioned phase change devices, there is a need to develop a chalcogenide-based thin film modifier that can be applied to memory and logic such as NAND or DRAM, and a semiconductor substrate and semiconductor device fabricated using the chalcogenide-based thin film modifier.

### RELATED ART DOCUMENTS

### Patent Documents

KR 10-1279925 B1

### DISCLOSURE

### Technical Problem

Therefore, the present invention has been made in view of the above problems, and it is one object of the present invention to provide an activated substrate-adsorbed precursor by activating a substrate-adsorbed precursor by providing a compound having a predetermined structure as a chalcogenide-based thin film modifier, a thin film with high quality under low-temperature deposition conditions due to excellent reactivity to completely remove ligands, and a semiconductor substrate and semiconductor device including the thin film.

The above and other objects can be accomplished by the present invention described below

### Technical Solution

In accordance with one aspect of the present invention, provided is a chalcogenide-based thin film modifier for activating a substrate-adsorbed precursor to provide an activated substrate-adsorbed precursor, wherein the substrate-adsorbed precursor has Ge, Sb, Te, Se, or Sn as a central metal, and a first ligand of the substrate-adsorbed precursor is replaced with a second ligand of the chalcogenide-based thin film modifier.

The chalcogenide-based thin film may have a film quality of Ge, GeTe, GST (GeSbTe), GSS (GeSbSe), SnTe, SST (SnSbTe), or GSST (GeSnSbTe).

The reaction gas replacement may be due to activation energy of the activated substrate-adsorbed precursor being lower than activation energy of the substrate-adsorbed precursor.

The first ligand may include both silicon and carbon, both nitrogen and carbon, or both oxygen and carbon.

The second ligand may have lower activation energy (E_{A}) than the first ligand of the substrate-adsorbed precursor (E_{A first ligand}>E_{A second ligand}), and the activation energy may be determined when reacting with a subsequently injected precursor compound.

The substrate-adsorbed precursor may not include a halogen, and the chalcogenide-based thin film modifier may include one or more halogens selected from iodine and bromine.

The chalcogenide-based thin film modifier may be a mixed gas obtained by mixing hydrogen iodide (HI) and hydrogen bromide (HBr) with an inert gas in a mole fraction of 1 to 99.

The chalcogenide-based thin film may be a germanium-tellurium thin film or a germanium support film constituting the germanium-tellurium thin film.

An antimony-tellurium thin film may be formed on an upper portion of the germanium-tellurium thin film.

The thin film may be a deposition film.

Here, the deposition may include atomic layer deposition (ALD), plasma-enhanced atomic layer deposition (PEALD), chemical vapor deposition (CVD), plasma-enhanced chemical vapor deposition (PECVD), metalorganic chemical vapor deposition (MOCVD), or low pressure chemical vapor deposition (LPCVD).

The chalcogenide-based thin film modifier may replace a reaction gas.

When the chalcogenide-based thin film modifier is used, the first ligand of a substrate-adsorbed precursor is replaced with the second ligand (e.g., halogen) of the chalcogenide-based thin film modifier to activate the substrate-adsorbed precursor. In the subsequent step, reaction may easily occur with the injected reaction precursor, so that reactivity is somewhat reduced, and a reaction compound that is safe to handle may be used.

For example, according to a mechanism, highly reactive TeH₂ is injected into a substrate-adsorbed precursor (e.g., substrate-Ge-guan) to form substrate-Ge—Te—H and Guan-H is released. Despite using the highly reactive reaction compound (e.g., TeH₂), the Guan ligand is difficult to be completely removed.

According to a mechanism of introducing a chalcogenide-based thin film modifier (e.g., H—I) into a substrate-adsorbed precursor (e.g., substrate-Ge-guan) to form substrate-Ge—I and release Guan-H, by the complete reaction, the ligand of the substrate-adsorbed precursor, i.e., hydrocarbon impurities, may be completely removed. In the following step, a chalcogenide thin film (e.g., substrate-Ge—Te—H) may be formed subsequently by injecting various tellurium precursors.

That is, the second ligand of the chalcogenide-based thin film modifier may have lower activation energy (E_{A}) than the first ligand of the substrate-adsorbed precursor (E_{A first ligand}>E_{A second ligand}), and the activation energy may be determined when reacting with a subsequently injected precursor compound.

The reaction gas replacement may be due to activation energy of the activated substrate-adsorbed precursor being lower than activation energy of the substrate-adsorbed precursor.

In accordance with another aspect of the present invention, provided is a semiconductor substrate including a substrate; and a thin film,
wherein the thin film is a film deposited using the chalcogenide-based thin film modifier described above.

In accordance with still another aspect of the present invention, provided is a semiconductor substrate including a substrate; and a thin film,
wherein the thin film includes a film formed by laminating an antimony-tellurium upper layer and a germanium-tellurium lower layer, and
the germanium-tellurium lower layer or the germanium support film constituting the germanium-tellurium lower layer is a film deposited while exchanging ligands using the chalcogenide-based thin film modifier described above.

The thin film may have a multi-layer structure with two or more layers.

The thin film may have carbon compounds as by-products in an amount of 3,000 counts/s or less as measured by SIMS.

The thin film may have a deposition rate of 0.3 Å/cycle or more.

The thin film may have an iodine atom content of 50 counts/s or more as measured by SIMS.

In accordance with yet another aspect of the present invention, provided is a semiconductor device including the semiconductor substrate described above

The semiconductor device may be a memory and logic including a phase change memory device, NAND, and DRAM.

### Advantageous Effects

According to the present invention, the present invention has an effect of providing a chalcogenide-based thin film modifier capable of improving the deposition rate by effectively removing the ligand of a substrate-adsorbed precursor compound, improving the thin film productivity by reducing the impurities of a thin film, and replacing a reaction gas.

In addition, the properties of a phase change device can be improved. In addition, the present invention has an effect of providing a method of manufacturing a thin film using the chalcogenide-based thin film modifier, and a semiconductor substrate and semiconductor device fabricated using the method.

In addition, when the chalcogenide-based thin film modifier is used, the first ligand of a substrate-adsorbed precursor is replaced with the second ligand (e.g., halogen) of the chalcogenide-based thin film modifier to activate the substrate-adsorbed precursor. As a result, in the subsequent step, reaction can easily occur with the injected reaction precursor, so that the reactivity is somewhat reduced, and a reaction compound that is safe to handle can be used.

In addition, according to the conventional mechanism, highly reactive TeH₂ is injected into a substrate-adsorbed precursor (e.g., substrate-Ge-guan) to form substrate-Ge—Te—H and Guan-H is released. To solve the problem of not being able to completely remove the Guan ligand despite using the highly reactive reaction compound (e.g., TeH₂), according to the mechanism of introducing a chalcogenide-based thin film modifier (e.g., H—I) into a substrate-adsorbed precursor (e.g., substrate-Ge-guan) to form substrate-Ge—I and release Guan-H, by the complete reaction, the ligand of the substrate-adsorbed precursor, i.e., hydrocarbon impurities, can be completely removed. In addition, a chalcogenide thin film (e.g., substrate-Ge—Te—H) can be formed subsequently by injecting various tellurium precursors.

### DESCRIPTION OF DRAWINGS

FIG. 1 is an image showing the thin film deposition of Example 1 obtained under conditions in which a chalcogenide-based thin film modifier was used before and after introduction of a precursor compound and no ammonia gas was introduced according to an embodiment of the present invention.

FIG. 2 is an image showing the thin film deposition of Example 2 obtained under conditions in which a chalcogenide-based thin film modifier was used before and after introduction of a precursor compound and no ammonia gas was introduced according to another embodiment of the present invention.

FIG. 3 is an image showing the thin film deposition of Comparative Example 1 using ammonia gas as a reaction gas without using a chalcogenide-based thin film modifier according to the prior art.

### BEST MODE

Hereinafter, a chalcogenide-based thin film modifier of the present invention, and a semiconductor substrate and semiconductor device fabricated using the same are described in detail.

The present inventors confirmed that, by providing a specific compound that effectively removes a ligand from a precursor compound using a metalloid as a central metal used to form a chalcogenide-based thin film, as a chalcogenide-based thin film modifier, the deposition rate of a thin film was greatly improved, and process by-products such as Cl, O, Si, H, NH, metals, and metal oxides, in particular, carbon, were significantly reduced. Based on these results, the present inventors conducted further studies on a chalcogenide-based low-temperature deposition thin film to complete the present invention.

Hereinafter, the chalcogenide-based thin film modifier, and the semiconductor substrate and semiconductor device including a thin film manufactured using the same are described in detail.

### Chalcogenide-Based Thin Film Modifier

In the present invention, the chalcogenide-based thin film modifier may be a material that activates a substrate-adsorbed precursor to provide an activated substrate-adsorbed precursor.

For example, the substrate-adsorbed precursor may have Ge, Sb, Te, Se, or Sn as a central metal, and may contain both silicon and carbon as ligands, or may contain both nitrogen and carbon as ligands and may be adsorbed onto a substrate, or may contain both oxygen and carbon as ligands and may be adsorbed onto the substrate.

In the case of such a substrate-adsorbed precursor, when the substrate-adsorbed precursor is modified into an activated substrate-adsorbed precursor by activating the substrate-adsorbed precursor into a predetermined structure to sufficiently release the ligand under low-temperature process conditions, the substrate-adsorbed precursor may be a substance that provides sufficient reactivity to replace a reaction gas as well as activation.

In the present invention, unless otherwise specified, the term “predetermined structure” refers to the exchange of a ligand contained in a substrate-adsorbed precursor with a specific halogen.

For example, the ligand of the substrate-adsorbed precursor may include both silicon and carbon, or both nitrogen and carbon.

Preferably, the substrate-adsorbed precursor does not include a halogen, and the chalcogenide-based thin film modifier includes one or more halogens selected from iodine and bromine.

As a specific example, the chalcogenide-based thin film modifier may be a mixed gas obtained by mixing hydrogen iodide (HI) and hydrogen bromide (HBr) with an inert gas in a mole fraction of 1 to 99. In terms of transport of gaseous substances and reaching the reaction surface, the chalcogenide-based thin film modifier is preferably a substance represented by the structure or a mixture of the substance and an inert gas. In this case, by suppressing side reactions and controlling the thin film growth rate, carbon compounds as by-products in a thin film may be greatly reduced. Accordingly, corrosion or deterioration may be prevented, and the effect of reaching a stoichiometric oxidation state may be obtained when forming a chalcogenide-based thin film.

As a specific example, the chalcogenide-based thin film modifier may be 3 N to 15 N hydrogen iodide, a gas mixture containing 1 to 99 mol % of 3 N to 15 N hydrogen iodide and an inert gas in an amount that allows a total amount to be 100 mol %, or an aqueous solution mixture containing 0.5 to 70 mol % of 3 N to 15 N hydrogen iodide and water in an amount that allows a total amount to be 100 mol %. Here, when the inert gas is nitrogen, helium, or argon with a purity of 4 N to 9 N, process by-products may be significantly reduced, step coverage may be excellent, thin film density may be improved, and the electrical properties of a thin film may be excellent.

Preferably, the chalcogenide-based thin film modifier may be 5 N to 6 N hydrogen iodide, a gas mixture containing 1 to 99 mol % of 5 N to 6 N hydrogen iodide and an inert gas in an amount that allows a total amount to be 100 mol %, or an aqueous solution mixture containing 0.5 to 70 mol % of 5 N to 6 N hydrogen iodide and water in an amount that allows a total amount to be 100 mol %. Here, the inert gas may be nitrogen, helium, or argon with a purity of 4 N to 9 N. In this case, side reactions may suppressed during the formation of a thin film, and the thin film growth rate may be controlled. Thus, process by-products in a thin film may be reduced, corrosion or deterioration may be prevented, and the crystallinity of a thin film may be improved. Thus, even when a thin film is formed on a substrate having a complex structure, step coverage and the thickness uniformity of a thin film may be greatly improved.

The chalcogenide-based thin film modifier may be preferably a compound having a purity of 99.9% or more, 99.95% or more, or 99.99% or more. For reference, when using a compound having a purity of less than 99%, impurities may remain in the thin film or cause side reactions with the precursor or reactant, so it is desirable to use a substance having a purity of 99% or more.

The chalcogenide-based thin film modifier may preferably have a vapor pressure of 1 atm at 180 to 240 K. Within this range, a material may be smoothly transferred into the chamber, thereby improving the reactivity of the chalcogenide-based thin film and improving the continuity and film quality of a thin film.

The chalcogenide-based thin film modifier may replace the reaction gas.

The reaction gas replacement may be due to the activation energy of the activated substrate-adsorbed precursor being lower than the activation energy of the substrate-adsorbed precursor.

In the present invention, the chalcogenide-based thin film modifier or a precursor compound described below may be vaporized and injected, and then may be subjected to plasma post-treatment. In this case, the growth rate of the thin film may be improved, and process by-products may be reduced.

The thin film may be a deposition film.

The deposition may be atomic layer deposition (ALD), plasma-enhanced atomic layer deposition (PEALD), chemical vapor deposition (CVD), plasma-enhanced chemical vapor deposition (PECVD), metalorganic chemical vapor deposition (MOCVD), or low pressure chemical vapor deposition (LPCVD).

The substrate may be a silicon wafer, an insulating film, or a dielectric film having —H and —OH terminal groups.

For example, the central metal of the substrate-adsorbed precursor described above may be a transition metal, preferably Ge or Te.

A material having a structure in which the ligand described above is bonded to the central metal may be used as the substrate-adsorbed precursor. Here, by activating the substrate-adsorbed precursor with the thin film activator described above, an activated substrate-adsorbed precursor may be obtained. In this case, process by-products may be significantly reduced and phase change characteristics may be excellent when forming a chalcogenide-based thin film.

When the substrate-adsorbed precursor is (N,N′-diisopropyl-dimethylguanidyl) (dimethylamino)germanium (II), the structure of the substrate-adsorbed precursor activated by the thin film activator may be -substrate-Ge—I. Here, it is preferable that the oxidation number of the central metal is divalent in terms of reducing the reaction energy.

The substrate-adsorbed precursor may be a germanium compound represented by Chemical Formula 1 below.

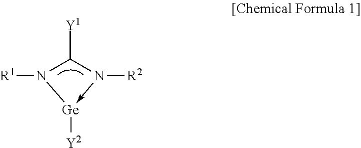

In Chemical Formula 1, Y¹ and Y² are each independently selected from R³, NR⁴R⁵, or OR⁶, and R¹ to R⁶ are each independently a C1-C7 alkyl group.

In Chemical Formula 1, Y¹ and Y² may be each independently —N(CH₃)₂, —N(CH₃) (CH₂CH₃), —CH₃, —CH(CH₃)₂, or —C(CH₃)₃.

In Chemical Formula 1, R¹ and R² may each independently be a germanium compound which is methyl, ethyl, propyl, or t-butyl.

The substrate-adsorbed precursor may be a germanium compound such as Ge(II)Br₂, Ge(II)Cl₂ (dioxane), or Ge(II)F₂ as a germanium(II) halide.

For example, when the substrate-adsorbed precursor is bis(trimethylsilyl) telluride, the structure of the substrate-adsorbed precursor activated by the thin film activator may be -substrate-Ge—Te—I, and it is preferable that the oxidation number of the central metal is divalent in terms of reducing the reaction energy.

In the present invention, the precursor compound used to form a thin film is a molecule having a central metal atom (M) and one or more ligands of C, N, Si, H, and X (halogens). When the precursor compound is a precursor having a vapor pressure of 1 mTorr to 100 Torr at 25° C., the effect of filling ligand leaving sites with the thin film activator described below may be maximized.

The central metal may be Ge, Sb, Te, Se, or Sn.

For example, the precursor compound may be a compound represented by Chemical Formula 1 below.

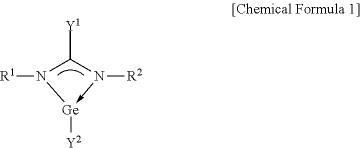

In Chemical Formula 1, Y¹ and Y² are each independently selected from R³, NR⁴R⁵, or OR⁶, and R¹ to R⁶ are each independently a C1-C7 alkyl group.

In Chemical Formula 1, Y¹ and Y² may each independently be —N(CH₃)₂, —N(CH₃)(CH₂CH₃), —CH₃, —CH(CH₃)₂, or —C(CH₃)₃.

In Chemical Formula 1, R¹ and R² may each independently be a germanium compound which is methyl, ethyl, propyl, or t-butyl.

As a specific example, the substrate-adsorbed precursor may be a germanium compound which is Ge(II)Br₂ (dioxane), Ge(II)Br₂, Ge(II)Cl₂, Ge(II)Cl₂ (dioxane), Ge(II)F₂(dioxane), or Ge(II)F₂.

As another example, the precursor compound may be a compound represented by Chemical Formula 2 below.

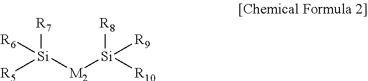

In Chemical Formula 2, M₂ is a metalloid and is different from germanium, tellurium, or selenium used in Chemical Formula 1, and R₅ to R₁₀ are each independently hydrogen or an alkyl group having 1 to 6 carbon atoms.

M₂ may be tellurium (Te) or selenium (Se).

R₅ to R₁₀ may be each independently CH₃ or C₂H₅.

For example, the compound represented by Chemical Formula 2 may include one or more structures selected from structures represented by Chemical Formulas 2-1 to 2-7 below.

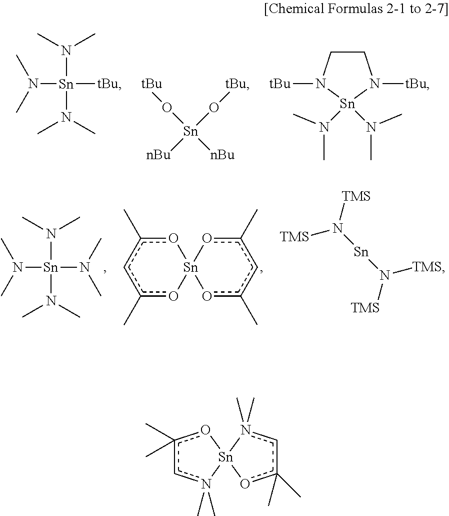

The precursor compounds described above are molecules having a metalloid as a central metal atom (M1, M2) and containing different ligands, and have a vapor pressure of 1 mTorr to 100 Torr at 25° C. In this case, the reaction with the chalcogenide-based thin film modifier described below may be maximized.

As the tellurium precursor compound and selenium precursor compound, bis(trimethylsilyl) telluride, tellurium tetrachloride, tellurium bromide, diphenyl ditelluride, tellurium dioxide, bis(trimethylsilyl)selenide, selenium dichloride, selenium tetrachloride, selenium dibromide, selenium tetrabromide, diphenyl selenide, selenium dioxide, or the like may be used. In this case, the reaction with halides described later may be maximized.

As a specific example, as the tellurium precursor compound, a compound represented by Chemical Formula 3-1 below may be used.

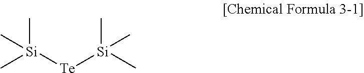

For example, the precursor compound may be mixed with a polar solvent and introduced into the chamber. In this case, the viscosity or vapor pressure of the precursor compound may be easily controlled.

The polar solvent may preferably be an amine solvent, as a specific example, dimethylamine, diethylamine, trimethylamine, or triethylamine. In this case, reactivity and solubility may be low. In addition, step coverage may be improved even when the deposition temperature is increased during thin film formation while containing an organic solvent that is easy to control moisture.

For example, the polar solvent may have a solubility (25° C.) of 200 mg/L or less, preferably 50 to 400 mg/L, more preferably 135 to 175 mg/L in water. Within this range, the reactivity toward the precursor compound may be reduced, and moisture may be easily managed.

In the present disclosure, solubility may be measured without any particular limitation by a measurement method or standard commonly used in the technical field to which the present invention pertains. For example, solubility may be measured by the HPLC method using a saturated solution.

Based on a total weight of the precursor compound and polar solvent, the polar solvent may be included in an amount of preferably 5 to 95 mol %, more preferably 10 to 90 mol %, still more preferably 40 to 90 mol %, most preferably 70 to 90 mol %.

When the content of the polar solvent being injected exceeds the upper limit, impurities are generated, increasing the resistance and the impurity value within a thin film. When the content of the polar solvent being injected is less than the lower limit, the effect of improving step coverage and reducing impurities such as chloride (Cl) ions due to solvent addition may be reduced.

### Thin Film

A thin film obtained using the above-described chalcogenide-based thin film modifier is included.

The thin film may have a multi-layer structure with two or more layers, or a multi-layer structure with two or three layers.

The thin film may form a germanium-tellurium thin film or a germanium support film constituting the germanium-tellurium thin film.

For example, the thin film may be obtained by reacting the activated substrate-adsorbed precursor having the structure represented by Chemical Formula 1 with the chalcogenide-based thin film modifier. In this case, a high-quality thin film may be manufactured without considering the reaction energy between reaction gases while using the activated substrate-adsorbed precursor.

For example, the excellent reactivity of the above-described activated substrate-adsorbed precursor and reaction gas may result from the activation energy of the activated substrate-adsorbed precursor being lower than the activation energy of the substrate-adsorbed precursor.

For example, the germanium-tellurium thin film may include an antimony-tellurium thin film on the upper portion thereof.

The thin film may be a deposition film.

The deposition may be atomic layer deposition (ALD), plasma-enhanced atomic layer deposition (PEALD), chemical vapor deposition (CVD), plasma-enhanced chemical vapor deposition (PECVD), metalorganic chemical vapor deposition (MOCVD), or low pressure chemical vapor deposition (LPCVD).

The thin film may contain carbon compounds as by-products in an amount of 3,000 counts/s or less, 1,000 counts/s or less, or 50 to 600 counts/s as measured by SIMS.

The thin film may have a deposition rate of 0.3 Å/cycle or more, 0.5 Å/cycle or more, or 0.7 to 2.0 Å/cycle as measured using an ellipsometer. Within this range, the continuity and roughness of a film in the plane direction and the density of a thin film may be improved.

The thin film may have an iodine atom content of 50 counts/s or more as measured by SIMS.

A step of adsorbing the chalcogenide-based thin film modifier onto a substrate, a step of purging the unabsorbed chalcogenide-based thin film modifier, a step of supplying the precursor compound represented by Chemical Formula 2 or 3 onto the substrate, a step of purging the residual precursor compound, a step of modifying the precursor compound with a separate chalcogenide-based thin film modifier, and a step of purging the residual chalcogenide-based thin film modifier may be set as a unit cycle, and the unit cycle may be repeated to form a thin film of desired thickness.

The thin film may be provided on SiO₂ on the substrate, but is not limited thereto, and —SiH, —SiH₂, —SiH₃, —SiOH, —Si(OH)₂, —Si(OH)₃, and —Si—O—Si— may be also included.

The thin film may be used in semiconductor devices, for example, phase change memory devices.

In addition, in the present invention, as a film formed by laminating an antimony-tellurium upper layer and a germanium-tellurium lower layer, the germanium-tellurium lower layer may provide a laminated film characterized by activating a precursor compound with a chalcogenide-based thin film modifier to obtain the activated precursor compound represented by Chemical Formula 1 or 2, and then modifying a ligand of the activated precursor compound by introducing a chalcogenide-based thin film modifier.

### Method of Manufacturing Thin Film

The thin film may be manufactured by a variety of methods. As the methods, methods including a step of forming a metalloid thin film including a germanium-tellurium-based material may be used without any particular limitation.

For example, the steps of forming a metalloid thin film including the germanium-tellurium-based material are as follows:

As the first step, a source gas containing a chalcogenide-based thin film modifier and a germanium precursor compound may be injected onto a substrate loaded into a chamber sequentially.

For example, the chalcogenide-based thin film modifier may contain one or more halogens selected from iodine and bromine, preferably iodine.

In the present disclosure, for example, a source gas containing a chalcogenide-based thin film modifier and a germanium precursor compound may be delivered to the deposition chamber using vapor flow control (VFC) using a mass flow controller (MFC), mass flow control (MFC) using a liquid mass flow controller (LMFC), or a liquid delivery system (LDS).

At this time, a mixed gas of one or more selected from the group consisting of argon (Ar), nitrogen (N₂), and helium (He) may be used as a carrier gas or dilution gas to move the source gas containing a chalcogenide-based thin film modifier and a germanium precursor compound onto the substrate, without being limited thereto.

In the present disclosure, for example, an inert gas, preferably the carrier gas or dilution gas may be used as the purge gas.

The chamber may be an atomic layer deposition (ALD) chamber, a plasma-enhanced atomic layer deposition (PEALD) chamber, a chemical vapor deposition (CVD) chamber, a plasma-enhanced chemical vapor deposition (PECVD) chamber, a metalorganic chemical vapor deposition (MOCVD) chamber, or a low pressure chemical vapor deposition (LPCVD) chamber.

The substrate loaded into the chamber may include a semiconductor substrate such as a silicon substrate or silicon oxide.

The substrate may further have a conductive layer or insulating layer formed thereon.

The substrate may be maintained at 50 to 500° C., 80 to 500° C., 80 to 350° C., or 80 to 200° C.

For example, the substrate may be heated to 50 to 300° C., as a specific example, 50 to 250° C., 50 to 200° C., or 70 to 200° C., and the chalcogenide-based thin film modifier and the precursor compound may be injected onto the substrate sequentially.

The chalcogenide-based thin film modifier and the germanium precursor compound may be injected onto the substrate in an unheated or heated state, respectively, and depending on the deposition efficiency, the chalcogenide-based thin film modifier or the germanium precursor compound may be injected in an unheated state and then the heating conditions may be adjusted during the deposition process. For example, the chalcogenide-based thin film modifier or the germanium precursor compound may be injected onto the substrate heated to 50 to 300° C. for 1 to 20 seconds.

The amount (mg/cycle) of the chalcogenide-based thin film modifier and germanium precursor compound injected into the chamber may may be determined based on the ratio of the amounts (mg/cycle) of the chalcogenide-based thin film modifier and precursor compound injected into the chamber used in the third step described below.

For example, the chalcogenide-based thin film modifier and the germanium precursor compound may be introduced in a ratio of 1:1 to 1:20, preferably 1:1 to 1:15, more preferably 1:1 to 1:10. Within this range, carbon compounds as by-products may be significantly reduced, and low-temperature process needs may be satisfied.

As the second step, one or more purging steps using an inert gas may be included. The inert gas may be the carrier gas or dilution gas described above.

In the step of purging the unabsorbed material, the amount of purge gas injected into the chamber is not particularly limited, and may be, for example, may be 10 to 100,000 times, preferably 50 to 50,000 times, more preferably 100 to 10,000 times the volume of the chalcogenide-based thin film modifier or germanium precursor compound injected into the chamber. Within this range, by sufficiently removing the chalcogenide-based thin film modifier and the unabsorbed germanium precursor compound, a thin film may be formed evenly and deterioration of film quality may be prevented. Here, the input amounts of the purge gas and germanium precursor compound are each based on one cycle, and the volume of the chalcogenide-based thin film modifier and germanium precursor compound refers to the volume of the vaporized precursor compound.

In the present disclosure, purging may be performed at preferably 1,000 to 50,000 sccm (standard cubic centimeter per minute), more preferably 2,000 to 30,000 sccm, still more preferably 2,500 to 15,000 sccm. Within this range, the thin film growth rate per cycle may be appropriately controlled. In addition, since deposition is performed as an atomic mono-layer or nearly an atomic mono-layer, the film quality may be improved.

As the third step, the chalcogenide-based thin film modifier is injected into the substrate to release the ligand of the germanium precursor compound adsorbed on the substrate and fill the leaving site with a halogen. In this case, by effectively releasing the precursor adsorbed on the substrate, the reaction rate may be improved, the thin film growth rate may be appropriately reduced, and carbon compounds as by-products may be significantly reduced.

For example, the halide may include one or more halogens selected from iodine and bromine, preferably iodine.

The feeding time (sec) of the chalcogenide-based thin film modifier on the surface of the substrate is preferably 0.01 to 10 seconds, more preferably 0.02 to 3 seconds, still more preferably 0.04 to 2 seconds, still more preferably 0.05 to 1 second per cycle. Within this range, the growth rate of a thin film may be reduced, the density of a thin film may be improved, and economic efficiency may be excellent.

In the present disclosure, the supply amount of the chalcogenide-based thin film modifier is based on a flow rate of 1 to 300 sccm/cycle at a chamber volume of 15 to 20 L, and more specifically, based on a flow rate of 10 to 100 sccm/cycle at a chamber volume of 18 L.

In the present disclosure, a method of transporting gas using a mass flow controller (MFC) method may be used to deliver the chalcogenide-based thin film modifier to the deposition chamber.

Preferably, the third step may further include a step of increasing the temperature inside the chamber to the deposition temperature before introducing the chalcogenide-based thin film modifier into the chamber; and/or a step of purging by injecting an inert gas into the chamber before introducing the chalcogenide-based thin film modifier into the chamber.

As the fourth step, one or more purging steps using an inert gas may be included. In the present disclosure, as the purge gas, for example, a carrier gas or a dilution gas may be used.

In the present disclosure, purging may be performed at preferably 1,000 to 50,000 sccm (standard cubic centimeter per minute), more preferably 2,000 to 30,000 sccm, still more preferably 2,500 to 15,000 sccm. Within this range, the thin film growth rate per cycle may be appropriately controlled. In addition, since deposition is performed as an atomic mono-layer or nearly an atomic mono-layer, the film quality may be improved.

The amount of purge gas injected into the chamber in the step of purging the unabsorbed chalcogenide-based thin film modifier is not particularly limited as long as the amount is an amount sufficient to remove the unabsorbed chalcogenide-based thin film modifier, but may be, for example, 10 to 100,000 times, preferably 50 to 50,000 times, more preferably 100 to 10,000 times. Within this range, by sufficiently removing the unabsorbed chalcogenide-based thin film modifier, a thin film may be evenly formed, and deterioration of film quality may be prevented. Here, the input amounts of the purge gas and chalcogenide-based thin film modifier are each based on one cycle, and the volume of the chalcogenide-based thin film modifier refers to the volume of the vaporized chalcogenide-based thin film modifier.

As a specific example, the chalcogenide-based thin film modifier is injected at a flow rate of 100 sccm for an injection time of 0.5 sec (per cycle). In the step of purging an unabsorbed deposition filler, when the purge gas is injected at a flow rate of 3000 sccm for an injection time of 5 seconds (per cycle), the amount of purge gas injected is 300 times the amount of chalcogenide-based thin film modifier injected.

Next, as the fifth step, by injecting a tellurium precursor compound into the substrate, the halogen bonded to the germanium central metal may be removed and a thin film bonded with tellurium may be formed.

For example, the tellurium precursor compound may be a compound represented by Chemical Formula 3 below.

For example, the method of forming a thin film may be performed at a deposition temperature of 50 to 300° C., preferably 50 to 250° C., more preferably 50 to 200° C., still more preferably 120 to 200° C. Within this range, process characteristics may be implemented, and a thin film having excellent film quality may be formed.

For example, the method of forming a thin film may be performed under a deposition pressure of 0.01 to 20 Torr, preferably 0.1 to 20 Torr, more preferably 0.1 to 10 Torr, most preferably 0.3 to 7 Torr. Within this range, a thin film of uniform thickness may be obtained.

In the present disclosure, the deposition temperature and the deposition pressure may be measured as temperature and pressure formed within the deposition chamber, or as temperature and pressure applied to the substrate within the deposition chamber.

As the sixth step, a purging step using an inert gas may be included.

In the purging step performed immediately after supplying the tellurium precursor compound, the amount of purge gas introduced into the chamber may be, for example, 10 to 10,000 times, preferably 50 to 50,000 times, more preferably 100 to 10,000 times the volume of reaction gas introduced into the chamber. Within this range, the desired effects may be sufficiently achieved. Here, the input amounts of purge gas and reaction gas are based on one cycle.

In the present disclosure, purging may be performed at preferably 1,000 to 50,000 sccm (standard cubic centimeter per minute), more preferably 2,000 to 30,000 sccm, still more preferably 2,500 to 15,000 sccm. Within this range, the thin film growth rate per cycle may be appropriately controlled. In addition, since deposition is performed as an atomic mono-layer or nearly an atomic mono-layer, the film quality may be improved.

In the method of forming a thin film, when necessary, the unit cycle may be repeated 1 to 99,999 times, preferably 10 to 10,000 times, more preferably 50 to 5,000 times, still more preferably 100 to 2,000 times. Within this range, the desired thickness of a thin film may be obtained, and the effects to be achieved in the present invention may be sufficiently achieved.

As a specific example, in the method of manufacturing a thin film, to deposit a thin film on a substrate positioned in the chamber, the above-described chalcogenide-based thin film modifier and two or more precursor compounds or a mixture of the precursor compounds and a polar solvent are prepared, respectively.

Then, the prepared precursor compound or a mixture of the precursor compounds and a non-polar solvent is injected into a vaporizer, changes into a vapor phase, is transferred to a deposition chamber, and is adsorbed on the substrate. Then, the ligand of the tellurium precursor compound is replaced by the chalcogenide-based thin film modifier, and the unabsorbed precursor compound is purged.

Next, the prepared tellurium precursor compound is injected into the vaporizer, changed into a vapor phase, transferred to the deposition chamber, and adsorbed onto the substrate. Then, purging is performed to remove the unabsorbed tellurium precursor compound.

In the present disclosure, for example, the chalcogenide-based thin film modifier and two or types of precursor compounds may be delivered to the deposition chamber using vapor flow control (VFC) using a mass flow controller (MFC) or a liquid delivery system (LDS) using a liquid mass flow controller (LMFC).

At this time, a mixed gas of one or more selected from the group consisting of argon (Ar), nitrogen (N₂), and helium (He) may be used as a carrier gas or dilution gas to move the chalcogenide-based thin film modifier and two or types of precursor compounds onto the substrate, without being limited thereto.

In the present disclosure, an inert gas as a purge gas is used to purge unreacted residues. Accordingly, in addition to excess reaction gas, generated byproducts may be removed.

As described above, in the method of forming a thin film, for example, a step of supplying a chalcogenide-based thin film modifier onto a substrate, a step of purging the unabsorbed chalcogenide-based thin film modifier, a step of adsorbing a germanium precursor compound onto a substrate, a step of purging the unabsorbed germanium precursor compound, a step of supplying the chalcogenide-based thin film modifier onto the substrate, a step of purging the unabsorbed chalcogenide-based thin film modifier, a step of supplying the tellurium precursor compound, and a step of purging the residual tellurium precursor compound may be set as a unit cycle. To form a thin film of desired thickness, the unit cycle may be repeated.

For example, the unit cycle may be repeated 1 to 99,999 times, preferably 10 to 1,000 times, more preferably 50 to 5,000 times, still more preferably 100 to 2,000 times. Within this range, the desired thin film properties may be well expressed.

When the injection time of the germanium precursor compound and the purge time in the first and second steps are a and b, respectively, the injection time of the halide and the purge time in the third and fourth steps are c and d, respectively, and the injection time of the tellurium precursor compound and the purge time in the fifth and sixth steps are e and f, respectively, 0.1≤a≤10, 2a≤b≤4a, 0.1<c≤10, 2c≤d≤8c, and 2<e≤10, 2e≤b≤8e may be satisfied at the same time.

When injecting the germanium precursor compound and the halides and performing purging, and injecting the tellurium precursor compound and performing purging are set as one cycle, the germanium thin film may have a deposition rate of 0.5 Å/cycle or more.

When injecting the germanium precursor compound and the halides and performing purging, and injecting the tellurium precursor compound and performing purging are set as one cycle, 1) the thin film may have a deposition rate of 0.5 to 2 Å/cycle or more, and 2) the thin film may have a density of 9.8 to 10.5 g/cm³ or more.

For example, the method of manufacturing a thin film may be performed using thin film manufacturing equipment including an ALD chamber; a first vaporizer for vaporizing a chalcogenide-based thin film modifier; a first transport means for transporting the vaporized chalcogenide-based thin film modifier into the ALD chamber; a second vaporizer for vaporizing a germanium thin film precursor; a second transport means for transporting the vaporized thin film precursor into the ALD chamber; a third vaporizer for vaporizing a tellurium thin film precursor; and a third transport means for transporting the vaporized thin film precursor into the ALD chamber. Here, the vaporizer and transport means are not particularly limited as long as the vaporizer and transport means are a vaporizer and transport means commonly used in the technical field to which the present invention belongs.

### Semiconductor Substrate

In addition, the present invention provides a semiconductor substrate, and the semiconductor substrate is fabricated using the method of forming a thin film of the present invention, or includes the thin film, in particular, a laminated film. In this case, the thickness uniformity, density, and reliability of the thin film may excellent.

The manufactured thin film may preferably have a deposition rate of 0.7 Å/cycle or more and a density of 9.8 g/cm³ or more. Within this range, the thin film may have excellent performance as a diffusion barrier, and phase change reliability may be improved, but the present invention is not limited thereto.

Here, for example, the halogen remaining in the thin film may be Br₂, Br, Br⁻, Cl₂, Cl, or Cl⁻. As the amount of halogen residual in the thin film decreases, the film quality is improved, which is desirable.

In addition, as the carbon content remaining in the thin film decreases, the phase transformation reliability in the above-described low-temperature deposition process is improved, which is desirable.

The thin film may include a film formed by laminating an antimony-tellurium upper layer and a germanium-tellurium lower layer. The germanium-tellurium lower layer or the germanium support film constituting the germanium-tellurium lower layer may be preferably a film deposited while exchanging ligands using the chalcogenide-based thin film modifier described above.

For example, when necessary, the thin film may have a multilayer structure of two or more layers, a multilayer structure of three or more layers, or a multilayer structure of two or three layers. As a specific example, the multilayer film with a two-layer structure may have a lower layer-middle layer structure, and the multilayer film with a three-layer structure may have a lower layer-middle layer-upper layer structure.

For example, the lower layer may be formed of one or more selected from the group consisting of Si, SiO₂, MgO, Al₂O₃, CaO, ZrSiO₄, ZrO₂, HfSiO₄, Y₂O₃, HfO₂, LaLuO₂, SisN₄, SrO, La₂O₃, Ta₂O₅, BaO, and TiO₂.

For example, the middle layer may be a metalloid-containing thin film, preferably a germanium-tellurium-based thin film or a germanium support film constituting the germanium-tellurium-based thin film.

For example, the upper layer may be a thin film containing a metalloid different from the above-described metalloid, preferably an antimony-tellurium-based thin film.

### Semiconductor Device

According to the present invention, a semiconductor device including the above-described semiconductor substrate may be provided.

For example, the semiconductor device may be a phase change memory device or the like.

Hereinafter, the present invention will be described in more detail with reference to the following preferred examples. However, these examples are provided for illustrative purposes only and should not be construed as limiting the scope and spirit of the present invention. In addition, it will be apparent to those skilled in the art that various changes and modifications may be made without departing from the spirit and scope of the present invention, and such changes and modifications are also within the scope of the appended claims.

### EXAMPLES

As precursor compounds, a compound having a structure represented by Chemical Formula 2-8 below and a compound having a structure represented by Chemical Formula 3-1 below were prepared, respectively.

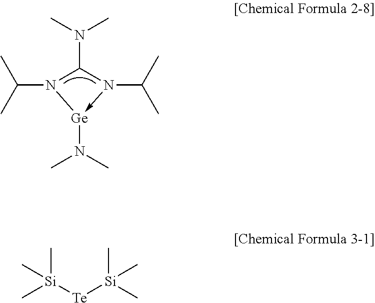

As chalcogenide-based thin film modifiers, 5N HBr and 5N HI were prepared.

An ALD deposition process was performed using the two types of precursor compounds and the chalcogenide-based thin film modifier, with the deposition process sequence according to the present invention as one cycle.

The specific experimental methods of Example and Comparative Example are as follows.

### Example 1

As the first step, 5 N HI as a chalcogenide-based thin film modifier was placed in a canister and supplied to a chamber at 100 sccm/cycle using a mass flow controller (MFC) at room temperature.

The chalcogenide-based thin film modifier was injected into a deposition chamber loaded with a substrate for 2 seconds, and then argon gas was supplied at 3000 sccm for 8 seconds to perform argon purging. At this time, the pressure inside the reaction chamber was controlled to 2.5 Torr.

As the second step, a precursor compound having the structure represented by Chemical Formula 2-8 was placed in a canister maintained at 25° C. and supplied to a separate vaporizer heated to 150° C. at a flow rate of 0.05 g/min using a liquid mass flow controller (LMFC) at room temperature. The precursor compound vaporized in the vaporizer was injected into the deposition chamber using a mass flow controller (MFC) for 1 second, and then argon gas was supplied at 3000 sccm for 5 seconds to perform argon purging. At this time, the pressure in the reaction chamber was controlled at 2.5 Torr.

As the third step, as a chalcogenide-based thin film modifier, 5 N HI was placed in a canister and supplied to the chamber at 100 sccm/cycle using a mass flow controller (MFC) at room temperature. The chalcogenide-based thin film modifier vaporized in the vaporizer was introduced into the deposition chamber loaded with a substrate for 2 seconds, and then argon gas was supplied at 3000 sccm for 8 seconds to perform argon purging. At this time, the pressure in the reaction chamber was controlled at 2.5 Torr.

As the fourth step, a precursor compound having the structure represented by Chemical Formula 3-1 was placed in a canister maintained at 25° C. and supplied to a separate vaporizer heated to 150° C. at a flow rate of 0.05 g/min using a liquid mass flow controller (LMFC) at room temperature. The precursor compound vaporized in the vaporizer was injected into the deposition chamber using a mass flow controller (MFC) for 1 second, and then argon gas was supplied at 3000 sccm for 5 seconds to perform argon purging. At this time, the pressure in the reaction chamber was controlled at 2.5 Torr.

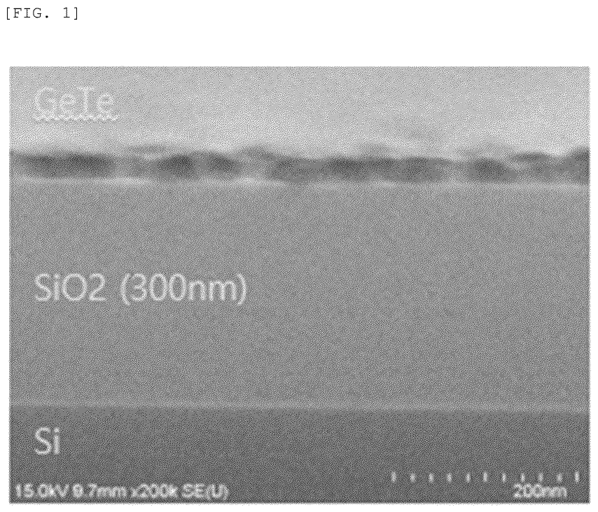

This process was repeated 200 to 400 times at a temperature of 130° C. to produce a self-limiting atomic layer thin film as shown in FIG. 1 below.

As shown in FIG. 1 below, the thin films each have a deposition thickness of 150 Å.

The thin film manufactured at a deposition temperature of 130° C. has a deposition rate of 0.85 Å/cycle.

In addition, the content of impurities contained in the thin film was measured.

At this time, the contents of impurities such as H, C, NH, OSi, Cl, and Ti were measured using secondary-ion mass spectrometry (SIMS) equipment.

Specifically, the impurity value was verified in the SIMS graph by considering the impurity content (counts) when an ion sputter was used to axially dig into the thin film and the sputter time was 50 seconds with little contamination on the surface of a substrate.

Among the confirmed SIMS results, the average impurity content of carbon (C) in the thin film was 151 counts/s. In addition to carbon, it was confirmed that Cl—, O, Si, H, NH, metals, and metal oxides remaining as process by-products were also reduced.

### Example 2

The same process as in Example 1 was performed except that the 130° C. temperature condition was replaced with the 170° C. temperature condition.

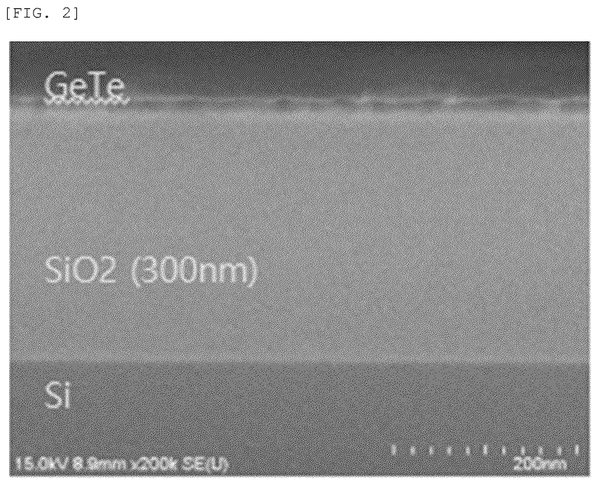

As a result, as shown in FIG. 2 below, the thin films each have a deposition thickness of 100 Å.

In addition, the content of impurities contained in the thin film was measured.

At this time, the contents of impurities such as H, C, NH, Cl, and Ti were measured using secondary-ion mass spectrometry (SIMS) equipment.

Specifically, the impurity value was verified in the SIMS graph by considering the impurity content (counts) when an ion sputter was used to axially dig into the thin film and the sputter time was 50 seconds with little contamination on the surface of a substrate.

Among the confirmed SIMS results, the average impurity content of carbon (C) in the thin film was 151 counts/s. In addition to carbon, it was confirmed that Cl—, O, Si, H, NH, metals, and metal oxides remaining as process by-products were also reduced.

### Comparative Example 1

The same process as in Example 1 was performed except that the second step was performed without the first step, and then the fourth step′ was performed without the third step.

Here, the fourth step′ is as follows.

As the fourth step′, a precursor compound having the structure represented by Chemical Formula 3-1 was placed in a canister maintained at 25° C. and supplied to a separate vaporizer heated to 150° C. at a flow rate of 0.05 g/min using a liquid mass flow controller (LMFC) at room temperature. Ammonia was injected at 500 sccm when the precursor compound vaporized in the vaporizer was injected into the deposition chamber using a mass flow controller (MFC) for 1 second, and then argon gas was supplied at 3000 sccm for 5 seconds to perform argon purging. At this time, the pressure in the reaction chamber was controlled at 2.5 Torr.

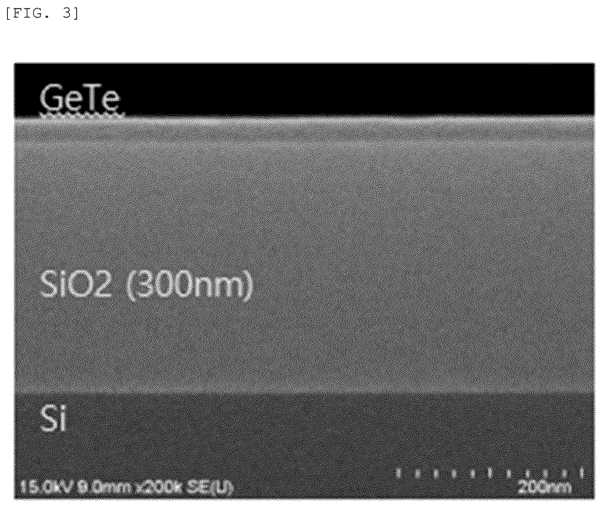

This process was repeated 200 to 400 times at a temperature of 130° C. to produce a self-limiting atomic layer thin film as shown in FIG. 3 below.

As shown in FIG. 3 below, the thin films each have a deposition thickness of 100 Å.

The thin film manufactured at a deposition temperature of 130° C. has a deposition rate of 0.45 Å/cycle.

In addition, the content of impurities contained in the thin film was measured.

At this time, the contents of impurities such as H, C, NH, O, Cl, and Ti were measured using secondary-ion mass spectrometry (SIMS) equipment.

Specifically, the impurity value was verified in the SIMS graph by considering the impurity content (counts) when an ion sputter was used to axially dig into the thin film and the sputter time was 50 seconds with little contamination on the surface of a substrate.

Among the confirmed SIMS results, the average impurity content of carbon (C) in the thin film was 1806 counts/s. In addition to carbon, it was confirmed that Cl—, O, Si, H, NH, metals, and metal oxides remaining as process by-products were also reduced.

### Comparative Example 2

The same process as in Comparative Example 1 was performed except that the step of injecting ammonia and performing purging was omitted. However, deposition did not proceed smoothly.

### Example 3

An antimony-tellurium-based thin film was laminated on the upper portion of the germanium-tellurium-based thin film manufactured in Example 1. As the antimony-tellurium-based thin film, an SbTe₃ precursor compound was used.

Based on these results, in the case of using the predetermined chalcogenide-based thin film modifier according to the present invention, compared to Comparative Example 1, in which the chalcogenide-based thin film modifier was not used and ammonia gas was used, and Comparative Example 2, in which both the chalcogenide-based thin film modifier and ammonia gas were not used, the deposition rate and deposition thickness were greatly improved. In addition, the content of carbon compounds as by-products was excellent enough to satisfy low-temperature deposition needs, and phase change reliability was also improved.

In particular, in the case of Example 1 using the chalcogenide-based thin film modifier of the present invention, despite the thin film being manufactured under low temperature conditions of 130° C., compared to Comparative Example 1 without using the chalcogenide-based thin film modifier, deposition rate per cycle was improved by more than 10%, and the content of carbon compounds as by-products was reduced up to 80% or more.

In addition, when comparing FIG. 1 according to Example 1 of the present invention, FIG. 2 according to Example 2, and FIG. 3 according to Comparative Example 1, it is confirmed that a thin film suitable for phase change is deposited by reducing hydrocarbon impurities.

Accordingly, when the predetermined compound was used as the chalcogenide-based thin film modifier of the present invention to manufacture a chalcogenide-based thin film, the thickness of the thin film and the increase rate in the deposition rate were improved. In addition, due to excellent impurity reduction characteristics, low temperature process needs were satisfied, and a thin film with excellent phase change reliability was formed.

1. A chalcogenide-based thin film modifier for activating a substrate-adsorbed precursor to provide an activated substrate-adsorbed precursor,
wherein the substrate-adsorbed precursor has Ge, Sb, Te, Se, or Sn as a central metal, and a first ligand of the substrate-adsorbed precursor is replaced with a second ligand of the chalcogenide-based thin film modifier.

2. The chalcogenide-based thin film modifier according to claim 1, wherein the chalcogenide-based thin film has a film quality of Ge, GeTe, GeSbTe, GeSbSe, SnTe, SnSbTe, or GeSnSbTe.

3. The chalcogenide-based thin film modifier according to claim 1, wherein the second ligand has lower activation energy (EA) than the first ligand of the substrate-adsorbed precursor (EA first ligand >EA second ligand), and the activation energy is determined when reacting with a subsequently injected precursor compound.

4. The chalcogenide-based thin film modifier according to claim 1, wherein the substrate-adsorbed precursor does not comprise a halogen, and the chalcogenide-based thin film modifier comprises one or more halogens selected from iodine and bromine.

5. The chalcogenide-based thin film modifier according to claim 1, wherein the chalcogenide-based thin film modifier is a mixed gas obtained by mixing hydrogen iodide (HI) and hydrogen bromide (HBr) with an inert gas in a mole fraction of 1 to 99.

6. The chalcogenide-based thin film modifier according to claim 1, wherein the chalcogenide-based thin film is a germanium-tellurium thin film or a germanium support film constituting the germanium-tellurium thin film, and an antimony-tellurium thin film is formed on an upper portion of the germanium-tellurium thin film.

7. The chalcogenide-based thin film modifier according to claim 1, wherein the thin film is a deposition film, wherein the deposition is atomic layer deposition (ALD), plasma-enhanced atomic layer deposition (PEALD), chemical vapor deposition (CVD), plasma-enhanced chemical vapor deposition (PECVD), metalorganic chemical vapor deposition (MOCVD), or low pressure chemical vapor deposition (LPCVD).

8. The chalcogenide-based thin film modifier according to claim 1, wherein the second ligand of the chalcogenide-based thin film modifier has lower activation energy (EA) than the first ligand of the substrate-adsorbed precursor (EA first ligand >EA second ligand), and the activation energy is determined when reacting with a subsequently injected precursor compound.

9. A semiconductor substrate comprising a substrate; and a thin film,
wherein the thin film is a film deposited using the chalcogenide-based thin film modifier according to claim 1.

10. A semiconductor substrate comprising a substrate; and a thin film,
wherein the thin film comprises a film formed by laminating an antimony-tellurium upper layer and a germanium-tellurium lower layer, and
the germanium-tellurium lower layer or the germanium support film constituting the germanium-tellurium lower layer is a film deposited while exchanging ligands using the chalcogenide-based thin film modifier according to claim 1.

11. The semiconductor substrate according to claim 10, wherein the thin film has a multi-layer structure with two or more layers.

12. The semiconductor substrate according to claim 10, wherein the thin film has a carbon impurity content of 3,000 counts/s or less as measured by SIMS, a deposition rate of 0.3 Å/cycle or more, and an iodine atom content of 50 counts/s or more as measured by SIMS.

13. A semiconductor device comprising the semiconductor substrate according to claim 10.
